(19) United States
(12) Patent Application Publication
(10) Pub. No.: US 2016/0315229 A1
(43) Pub. Date: Oct. 27, 2016

(54) LIGHT EMITTING DIODE PACKAGE UTILIZING QUANTUM DOTS

(71) Applicant: HON HAI PRECISION INDUSTRY CO., LTD., New Taipei (TW)

(72) Inventors: FENG-YUEN DAI, New Taipei (TW); CHAU-JIN HU, New Taipei (TW); PO-CHOU CHEN, New Taipei (TW); CHIH-PING HSU, New Taipei (TW)

(21) Appl. No.: 14/866,383

(22) Filed: Sep. 25, 2015

(30) Foreign Application Priority Data
Apr. 23, 2015 (CN) 201510196172.5

(51) Int. Cl. H01L 33/50; H01L 33/48; H01L 33/52; H01L 33/60

(52) U.S. Cl. CPC H01L 33/504; H01L 33/60; H01L 33/483; H01L 33/52; H01L 33/508

(57) ABSTRACT

A light emitting diode (LED) package includes a substrate having a first surface and a second surface located opposite at the first surface, an LED chip mounted on the first surface of the substrate, a reflector cup mounted on the first surface of the substrate and surrounding the LED chip therein, and an encapsulation layer located on the reflector cup. The encapsulation layer includes a glue and a plurality of quantum dots mixed in the glue. The quantum dots having a plurality of different diameters and configured to absorb light emitted from the LED chip and thereby become excited to generate light with different wavelengths from the light emitted from the LED chip.

### CROSS-REFERENCE TO RELATED APPLICATIONS

This application claims priority to Chinese Patent Application No. 201510196172.5 filed on Apr. 23, 2015, the contents of which are incorporated by reference herein.

### FIELD

The subject matter herein generally relates to a light emitting diode (LED) package.

### BACKGROUND

An LED chip generally generates monochromatic light. An LED package can generate white light generally through two following ways, one way is arranging a red LED chip, a green LED chip and a blue LED chip together. light respectively emitted from the red LED chip, the green LED chip and the blue LED chip is mixed to generate a white light. The other way is to configure a blue LED chip with a yellow phosphor, light emitted from the blue LED chip excites the yellow phosphor to generate white light.

### BRIEF DESCRIPTION OF THE DRAWINGS

Implementations of the present technology will now be described, by way of example only, with reference to the attached figures.

FIG. 1 is a cross sectional view of an LED package in accordance with a first embodiment of the present disclosure.

FIG. 2 is a cross sectional view of a quantum dots which is enlarged of FIG. 1.

FIG. 3 is a diagrammatic view for illustrating the quantum dots excited by blue light emitted form an LED chip of the LED package in FIG. 1.

FIG. 4 is a light path diagrammatic view of the LED package of FIG. 1.

FIG. 5 is a cross sectional view of a LED package in accordance with a second embodiment of the present disclosure.

FIG. 6 is a cross sectional view of an LED package in accordance with a third embodiment of the present disclosure.

### DETAILED DESCRIPTION OF EMBODIMENTS

It will be appreciated that for simplicity and clarity of illustration, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure. The description is not to be considered as limiting the scope of the embodiments described herein.

The term “comprising” means “including, but not necessarily limited to”; it specifically indicates open-ended inclusion or membership in a so-described combination, group, series and the like.

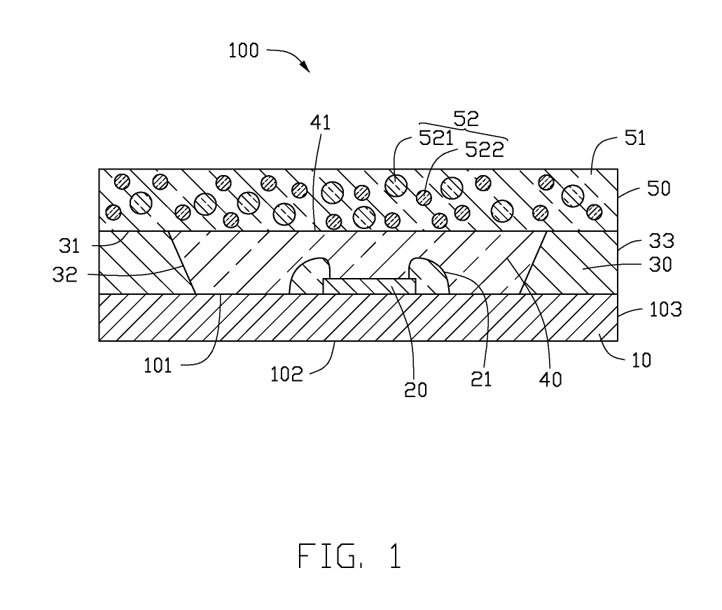

As illustrated in FIG. 1, a light emitting diode (LED) package of a first embodiment of the present disclosure includes a substrate 10, an LED chip 20 and a reflector cup 30 mounted on the substrate 10, a colloid 40 filled in the reflector cup 30 and a encapsulation layer 50 located on the reflector cup 30.

The substrate 10 is made of heat dissipation material. The substrate 10 includes a first surface 101, a second surface 102 located opposite to the first surface 101 and an outer periphery 103 connecting the first surface 101 and the second surface 102. The LED chip 20 is mounted on the first surface 101 of the substrate 10 and coupled with the substrate by wires 21. In the illustrated embodiment, the LED chip 20 generates blue light.

The reflector cup 30 is mounted on the first surface 101 of the substrate 10 and surrounds the LED chip 20 and the wires 21 therein. The reflector cup 30 includes a top surface 31, an inside wall 32 extending downward and aslant from an inner edge of the top surface 31 towards the first surface 101 of the substrate 10, and an outside wall 33 extending from an outer edge of the top surface 31 towards the first surface 101 of the substrate 10. The outside wall 33 is perpendicular to the first surface 101 of the substrate 10. The outside wall 33 is coplanar with the outer periphery 103 of the substrate 10. The inside wall 32 can be further covered by a reflecting material to reflect light. Light emitted from the LED chip 20 can be reflected by the inside wall 32 to exit from a top end of the reflector cup 30.

The colloid 40 is made of transparent material. The colloid 40 is filled in the reflector cup 30 to cover the LED chip 20 and wires 21 therein. A top end 41 of the colloid 40 is coplanar with the top surface 31 of the reflector cup 30. The colloid 40 can prevent the LED chip 20 from a water vapor or a dust.

The encapsulation layer 50 is located on the reflector cup 30 to seal the colloid 40 in the reflector cup 30. A thickness of the encapsulation layer 50 is uniform, an outer periphery of the encapsulation layer 50 is coplanar with the outside wall 33 of the reflector cup 30. The encapsulation layer 50 includes a glue 51 and a plurality of quantum dots 52 mixed evenly in the glue 51. In the illustrated embodiment, the glue 51 has the same material with the colloid 40.

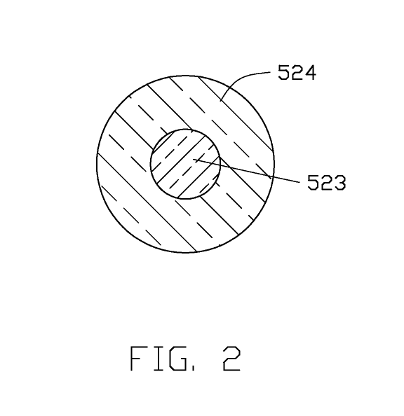

As illustrated in FIG. 2, the quantum dots 52 each includes a crystal layer 523 and a covering layer 524. The crystal layer 523 is substantially a grain shape. The covering layer 524 covers the crystal layer 523 on entirely outside surface. The crystal layer 523 can be made of granular crystal reacted by II-VI compounds and III-V compounds, the crystal layer 523 also can be made of II-VI compounds or III-V compounds. The II-VI compounds includes BeS, BeSe, BeTe, MgSe, CdS, CdSe, CdTe; the III-V compounds includes AN, AlP, AlAs, AlSb, GaP, GaAs, InP, InAs. Different diameters or different materials of the quantum dots 52 are excited to generate different light. The cover layer 524 can be made of inorganic modules or organic molecule. The quantum dots 52 can be ball-shaped. A diameter of the quantum dots 52 is 2-20 nm.

In the illustrated embodiment, the quantum dots 52 include a plurality of first quantum dots 521 and a plurality of second quantum dots 522. The first quantum dots 521 and the second quantum dots 522 are mixed in the glue 51 according to a pre-determined proportion. At least one embodiment, a density of the first quantum dots 521 in the glue 51 is uniform and equal to a density of the second quantum dots 522 in the glue 51. The proportion for mixing the first quantum dots 521 and the second quantum dots 522 depends on a demand of a color temperature value of the LED package.

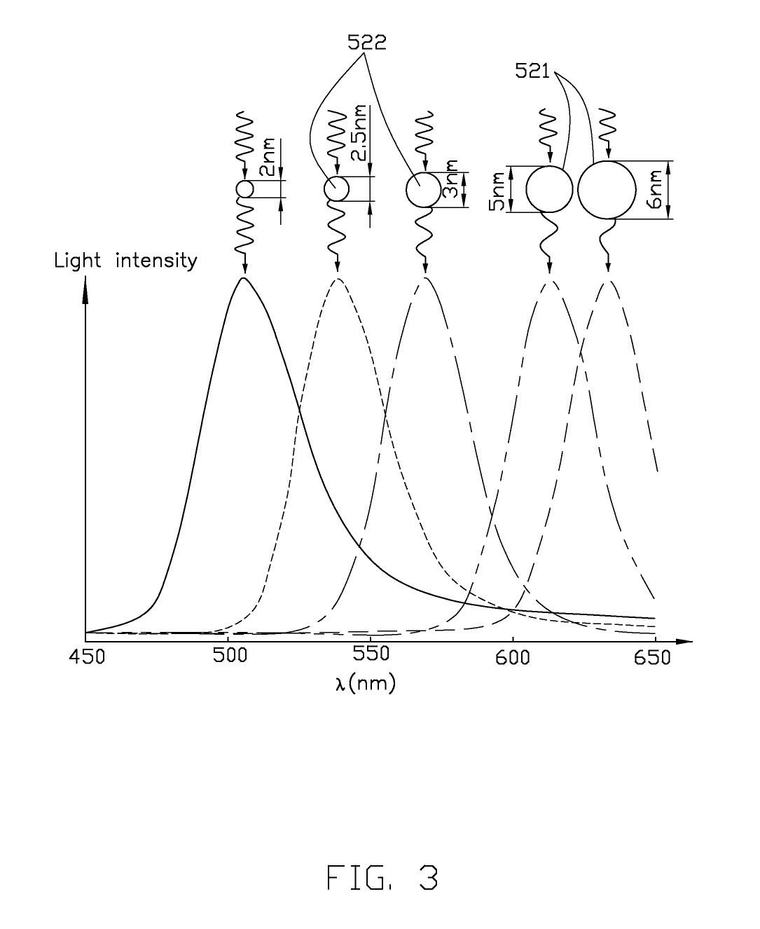

As illustrated in FIG. 3, the first quantum dots 521 and the second quantum dots 522 have the same material. A wavelength of the light emitted from the LED chip 20 and then excited by the quantum dots 52 is in direction proportion to the diameter of the quantum dots 52. In the illustrated embodiment, a diameter of the first quantum dots 521 is in a range of 5-6 nm, the first quantum dots 521 with the diameter between 5 nm and 6 nm absorbs blue light emitted from the LED chip 20 to excite red light with a wavelength 600 nm and 650 nm; a diameter of the second quantum dots 522 is in a range of 2.5-3 nm, the second quantum dots 522 with the diameter between 2.5 nm and 3 nm absorbs blue light emitted from the LED chip 20 to excite green light with a wavelength between 500 nm and 550 nm.

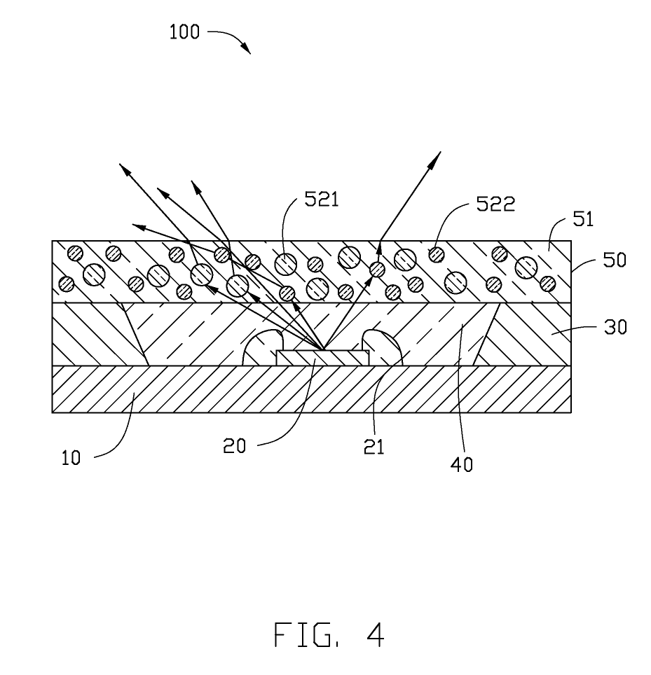

As illustrated in the FIG. 4, light emitted from the LED chip 20 enters the encapsulation layer 50 to excite the quantum dots 52 through the colloid 40. The first quantum dots 521 and the second quantum dots 522 absorb the light to excite a red light and a green light respectively. The red light excited by the first quantum dots 521, the blue light excited from the second quantum dots 522 and the blue light emitted from the LED chip 20 mix to be a white light and exit from a top end of the encapsulation layer 50.

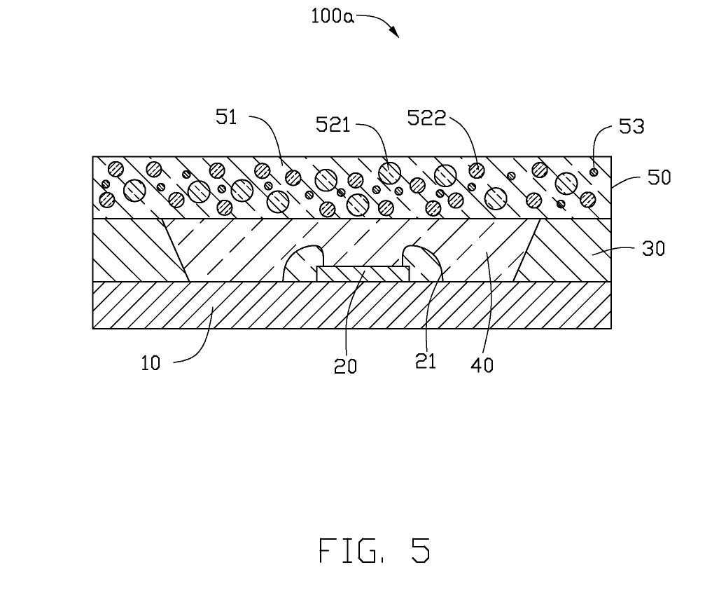

Referring to FIG. 5, an LED package 100a of a second embodiment of the present disclosure is similar to the LED package 100 of the first embodiment. The encapsulation layer 50 of the LED package 100a further includes a plurality of scatterers 53 mixed in the glue 51. The scatterers 53 are made of reflective material and reflect light emitted from the LED chip 20 towards the quantum dots 52.

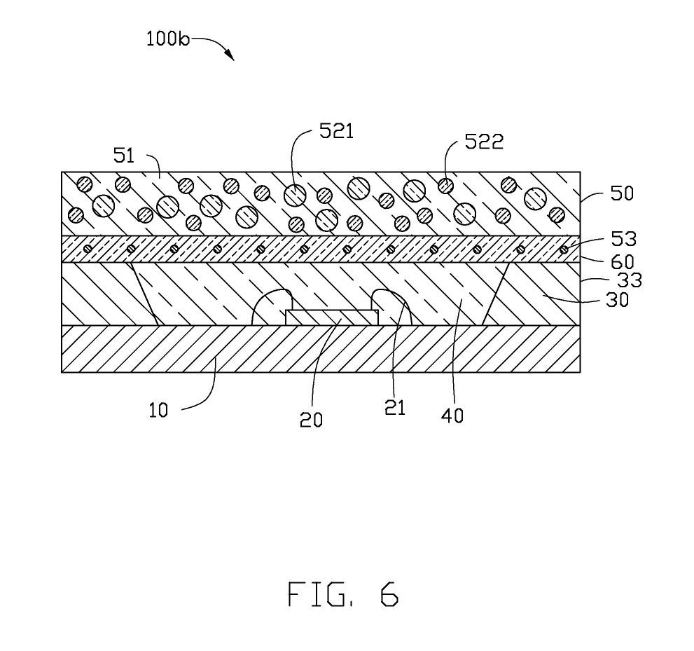

Referring to FIG. 6, an LED package 100b of a third embodiment of the present disclosure is similar to the LED package 100 of the first embodiment. The LED package 100b further includes a diffusion layer 60. The diffusion layer 60 is made of colloid 51 and the scatterers 53 mixed in the colloid 51. The diffusion layer 60 is located between the reflector cup 30 and the encapsulation layer 50. An outer periphery of the diffusion layer 60 is coplanar with the outer periphery of the encapsulation layer 50 and the outside wall 33 of the reflector cup 30.

The embodiments shown and described above are only examples. Many details are often found in the art such as the other features of an LED package. Therefore, many such details are neither shown nor described. Even though numerous characteristics and advantages of the present technology have been set forth in the foregoing description, together with details of the structure and function of the present disclosure, the disclosure is illustrative only, and changes can be made in the detail, including in matters of shape, size and arrangement of the parts within the principles of the present disclosure up to, and including the full extent established by the broad general meaning of the terms used in the claims. It will therefore be appreciated that the embodiments described above can be modified within the scope of the claims.

1. A light emitting diode (LED) package, comprising:
a substrate having a first surface and a second surface located opposite at the first surface;
an LED chip mounted on the first surface of the substrate;
a reflector cup mounted on the first surface of the substrate and surrounding the LED chip therein; and
an encapsulation layer located on the reflector cup, the encapsulation layer comprising a glue and a plurality of quantum dots mixed in the glue, the quantum dots having a plurality of different diameters and configured to absorb light emitted from the LED chip and thereby become excited to generate light with different wavelengths from the light emitted from the LED chip, the light generated by the quantum dots combining with the light from the LED chip to form a white light.

2. The LED package of claim 1, wherein the quantum dots is made of the same material, a wavelength of the light emitted from the LED chip and then excited by the quantum dots is in direction proportion to the diameter thereof

3. The LED package of claim 1, wherein the quantum dots each comprises a crystal layer and a covering layer covering the crystal layer on entirely outside surface.

4. The LED package of claim 3, wherein the crystal layer is substantially a grain shape and is made of granular crystal reacted by II-VI compounds and III-V compounds.

5. The LED package of claim 1, wherein the quantum dots is ball-shaped.

6. The LED package of claim 5, wherein a diameter of the quantum dots is in a range of 2-20 nm.

7. The LED package of claim 1, wherein the quantum dots comprises a plurality of first quantum dots and a plurality of second quantum dots.

8. The LED package of claim 7, wherein a density of the first quantum dots in the glue is uniform and equal to a density of the second quantum dots in the glue.

9. The LED package of claim 8, wherein a diameter of the first quantum dots is in a range of 5-6 nm, a diameter of the second quantum dots is in a range of 2.5-3 nm.

10. The LED package of claim 7, wherein the LED chip generates blue light, the first quantum dots absorbs the light emitted from the LED chip to be excited to generate red light, the second quantum dots absorbs the light emitted from the LED chip to be excited to generate green light.

11. The LED package of claim 1, wherein the reflector cup comprises a top surface, an inside wall extending downward and aslant from an inner edge of the top surface towards the first surface of the substrate and outside wall extending from an outer edge of the top surface towards the first surface of the substrate.

12. The LED package of claim 11, wherein the outside wall is perpendicular to the first surface of the substrate and is coplanar with an outer periphery of the substrate.

13. The LED package of claim 11 further comprising a colloid, wherein the colloid is filled in the reflector cup to cover the LED chip therein, a top end of the colloid is coplanar with the top surface of the reflector.

14. The LED package of claim 11 further comprising a diffusion layer made of a colloid and a plurality of scatterers mixed in with the colloid, wherein the diffusion layer being located between the reflector cup and the encapsulation layer, an outer periphery of the diffusion layer is coplanar with an outer periphery of the encapsulation layer and an outer side wall of the reflector cup.

15. The LED package of claim 1, wherein the encapsulation layer further comprises a plurality of scatterers mixed in the glue.

16. The LED package of claim 1, further comprising a diffusion layer, wherein the diffusion layer is located between the reflector cup and the encapsulation layer.
